(19) United States
(12) Patent Application Publication
(10) Pub. No.: US 2020/0286966 A1
(43) Pub. Date: Sep. 10, 2020

(54) TRANSPARENT DISPLAY PANEL AND DISPLAYING METHOD OF SAME

(71) Applicant: Wuhan China Star OptoelectronicsTechnology Co., Ltd., Wuhan (CN)

(72) Inventor: Yong YANG, Wuhan (CN)

(73) Assignee: Wuhan China Star Optoelectronics Technology Co., Ltd., Wuhan (CN)

(21) Appl. No.: 16/488,944

(22) PCT Filed: May 8, 2019
(86) PCT No.: PCT/CN2019/085948

§ 371 Date: Aug. 27, 2019

(30) Foreign Application Priority Data
Mar. 4, 2019 (CN) 201910160366.8

(51) Int. Cl. H01L 27/32; G02F 1/1334

(52) U.S. Cl. CPC H01L 27/3232; H01L 27/3244; G02F 2201/44; G02F 1/1334

(57) ABSTRACT

A transparent display panel and a displaying method of the same are provided. The transparent display panel includes an organic light emitting module and a polymer dispersed liquid crystal module. The polymer dispersed liquid crystal module includes a lower substrate and a display surface. The organic light emitting module is disposed on another side of the lower substrate. The organic light emitting module includes a display surface. The display surface of the organic light emitting module faces an opposite direction of the display surface of the polymer dispersed liquid crystal module.

### FIELD OF INVENTION

The present disclosure relates to display technologies, and more particularly, to a transparent display panel and a displaying method of the same.

### BACKGROUND OF INVENTION

Transparent displays are favored by people for their high transparency and unique display application effects, and are often displayed as window displays or head-up displays. However, due to low contrast, transparent displays often result in poor viewing performance, especially when ambient is brighter, which has a great influence on a display image. If a liquid crystal display (LCD) is used as a transparent display panel, aperture ratio of a backlight module of the LCD, a color resistance (CF), and a polarizer, and liquid crystal efficiency may cause transmittance of the transparent display to be lower, and then the light utilization rate is lower. At present, transparent display technology is gradually shifting from LCD displays to organic light emitting displays (OLEDs). However, the OLED display technology has lower brightness and higher reflectivity due to device material limitations, resulting in lower contrast.

Therefore, there is a need to solve the above problems.

### SUMMARY OF INVENTION

In view of the above, the present disclosure provides a transparent display panel and a displaying method of the same to resolve above-mentioned technical problem.

In order to achieve above-mentioned object of the present disclosure, one embodiment of the disclosure provides a transparent display panel including an organic light emitting module and a polymer dispersed liquid crystal module. The polymer dispersed liquid crystal module includes a lower substrate and a display surface. The organic light emitting module is disposed on another side of the lower substrate. The organic light emitting module comprises a display surface. The display surface of the organic light emitting module faces an opposite direction of the display surface of the polymer dispersed liquid crystal module.

In one embodiment of the disclosure, the polymer dispersed liquid crystal module includes a lower electrode layer disposed on a lower surface of the lower substrate, a polymer dispersed liquid crystal material disposed under the lower electrode layer, and an upper electrode layer disposed under the polymer dispersed liquid crystal material.

In one embodiment of the disclosure, the polymer dispersed liquid crystal module further includes an upper substrate disposed under the upper electrode layer and a polarizer sheet disposed under the upper substrate. A thickness of the polymer dispersed liquid crystal material is one fourth of a wavelength of incident light.

In one embodiment of the disclosure, the organic light emitting module and the polymer dispersed liquid crystal module share the lower substrate. The organic light emitting module includes a thin film transistor layer disposed on the lower substrate, an anode layer disposed on the thin film transistor layer, a hole transporting layer disposed on the anode layer, a light emitting layer disposed on the hole transporting layer, an electron transporting layer disposed on the light emitting layer, and a cathode layer disposed on the electron transporting layer.

In one embodiment of the disclosure, the transparent display panel further includes a cover plate disposed on the cathode layer.

In one embodiment of the disclosure, the organic light emitting module includes a thin film transistor layer disposed on the lower substrate, an anode layer disposed on the thin film transistor layer, a hole transporting layer disposed on the anode layer, a light emitting layer disposed on the hole transporting layer, an electron transporting layer disposed on the light emitting layer, and a cathode layer disposed on the electron transporting layer.

In one embodiment of the disclosure, the transparent display panel further includes a cover plate disposed on the cathode layer.

Furthermore, another embodiment of the disclosure provides a displaying method of a transparent display panel. The transparent display panel includes an organic light emitting module and a polymer dispersed liquid crystal module. The polymer dispersed liquid crystal module includes a lower substrate and a display surface. The organic light emitting module is disposed on another side of the lower substrate. The organic light emitting module includes a display surface. The display surface of the organic light emitting module faces an opposite direction of the display surface of the polymer dispersed liquid crystal module. The displaying method includes steps of:

the organic light emitting module turning on or turning off corresponding pixels according to an image signal;

the polymer dispersed liquid crystal module driving the polymer dispersed liquid crystal corresponding to the pixels turning on by the organic light emitting module as a scattering state; and

the polymer dispersed liquid crystal module driving the polymer dispersed liquid crystal corresponding to the pixels turning off by the organic light emitting module as a transparent state.

In one embodiment of the disclosure, the organic light emitting module is turned off and the polymer dispersed liquid crystal module is turned on to display when ambient light is greater than a predetermined luminance.

In one embodiment of the disclosure, the organic light emitting module and the polymer dispersed liquid crystal module are both turned on to undergo a transparent display when ambient light is lower than a predetermined luminance.

In comparison with prior art, the disclosure of the transparent display panel and the displaying method of the transparent display include the organic light emitting module disposed on another side of the lower substrate. The display surface of the organic light emitting module faces an opposite direction of the display surface of the polymer dispersed liquid crystal module. The polymer dispersed liquid crystal module driving the polymer dispersed liquid crystal corresponding to the pixels turning on by the organic light emitting module as a scattering state. The polymer dispersed liquid crystal module driving the polymer dispersed liquid crystal corresponding to the pixels turning off by the organic light emitting module as a transparent state. So that an embodiment of the transparent display panel of the disclosure behaves as a reflective display under strong ambient light to reduce power consumption and behave as a transparent display when ambient is darker and modulate ambient light by polymer dispersed liquid crystal to enhance contrast.

### BRIEF DESCRIPTION OF DRAWINGS

FIG. 1 is schematic view of a structure of a transparent display panel according to an embodiment of the present disclosure.

FIG. 2 is a schematic view of a structure of a transparent display panel according to another embodiment of the present disclosure.

FIG. 3 is a schematic applying view of a transparent display panel according to an embodiment of the present disclosure.

FIG. 4 is another schematic applying view of a transparent display panel according to an embodiment of the present disclosure.

FIG. 5 is a schematic flowchart of a displaying method of the transparent display panel according to an embodiment of the present disclosure.

### DETAILED DESCRIPTION OF PREFERRED EMBODIMENTS

The following description of the embodiments is provided by reference to the following drawings and illustrates the specific embodiments of the present disclosure. Directional terms mentioned in the present disclosure, such as “up,” “down,” “top,” “bottom,” “forward,” “backward,” “left,” “right,” “inside,” “outside,” “side,” “peripheral,” “central,” “horizontal,” “peripheral,” “vertical,” “longitudinal,” “axial,” “radial,” “uppermost” or “lowermost,” etc., are merely indicated the direction of the drawings. Therefore, the directional terms are used for illustrating and understanding of the application rather than limiting thereof.

Referring to FIG. 1, one embodiment of the disclosure provides a transparent display panel 1000 including an organic light emitting module 100 and a polymer dispersed liquid crystal (PDLC) module 200. The polymer dispersed liquid crystal module 200 includes a lower substrate 21 and a display surface 20. The organic light emitting module 100 is disposed on another side of the lower substrate 21. The organic light emitting module 100 comprises a display surface 10. The display surface 10 of the organic light emitting module 100 faces an opposite direction of the display surface 20 of the polymer dispersed liquid crystal module 200.

In one embodiment of the disclosure, the polymer dispersed liquid crystal module 200 includes a lower electrode layer 22 disposed on a lower surface of the lower substrate 21, a polymer dispersed liquid crystal material 23 disposed under the lower electrode layer 22, and an upper electrode layer 24 disposed under the polymer dispersed liquid crystal material 23.

In detail, taking a polymer dispersed liquid crystal material of positive dielectric heterogeneity as an example, when there is no external electric field, the liquid crystal materials are irregularly arranged, thereby causing scattering of incident light. When an electric field is applied, the liquid crystal material is regularly arranged, thereby causing partial reflection and partial transmission of the incident light. Therefore, the image can be observed regardless of which side of the double-sided display 200.

In detail, a thickness of the polymer dispersed liquid crystal material 23 is one fourth of a wavelength λ of incident light. The wavelength λ of the incident light is within range of wavelengths of visible light or is a mean of wavelengths of visible light, the disclosure is not limit thereto.

In detail, the polymer dispersed liquid crystal module 100 further includes a thin film transistor layer (not show) disposed under the lower substrate 21.

In detail, the lower electrode layer 22 and the upper electrode layer 24 are configured for controlling twisting of the polymer dispersed liquid crystal.

One embodiment of the disclosure, the polymer dispersed liquid crystal module 200 further includes an upper substrate 25 disposed under the upper electrode layer 24 and a polarizer sheet 26 disposed under the upper substrate 25.

In detail, the transparent display panel 1000 may further include an anti-reflection film, which may be a multilayer film structure or a single layer film having a film thickness equal to ¼ of a wavelength λ of incident light.

In one embodiment of the disclosure, the organic light emitting module 100 and the polymer dispersed liquid crystal module 200 share the lower substrate 21. The organic light emitting module 100 includes a thin film transistor layer 11 disposed on the lower substrate 21, an anode layer 12 disposed on the thin film transistor layer 11, a hole transporting layer 13 disposed on the anode layer 12, a light emitting layer 14 disposed on the hole transporting layer 13, an electron transporting layer 15 disposed on the light emitting layer 14, and a cathode layer 16 disposed on the electron transporting layer 15.

In detail, the anode layer 12, the hole transporting layer 13, the light emitting layer 14, the electron transporting layer 15, and the cathode layer 16 constitute an organic light emitting pixel 101 of the organic light emitting module 100.

In detail, the cathode layer 16 includes transparent electrode material.

In detail, the transparent electrode material is indium tin oxide.

In detail, the lower substrate 21 is transparent substrate. The anode layer 12 of the organic light emitting module 100 includes metallic electrode material to enhance reflection of light beams incident the polymer dispersed liquid crystal module 200.

In detail, because the metal electrode occupies a small area of the transparent display panel 1000, the reflection effect of the metal electrode does not affect the effect of the transparent display.

In one embodiment of the disclosure, the transparent display panel 1000 further includes a cover plate 17 disposed on the cathode layer 16.

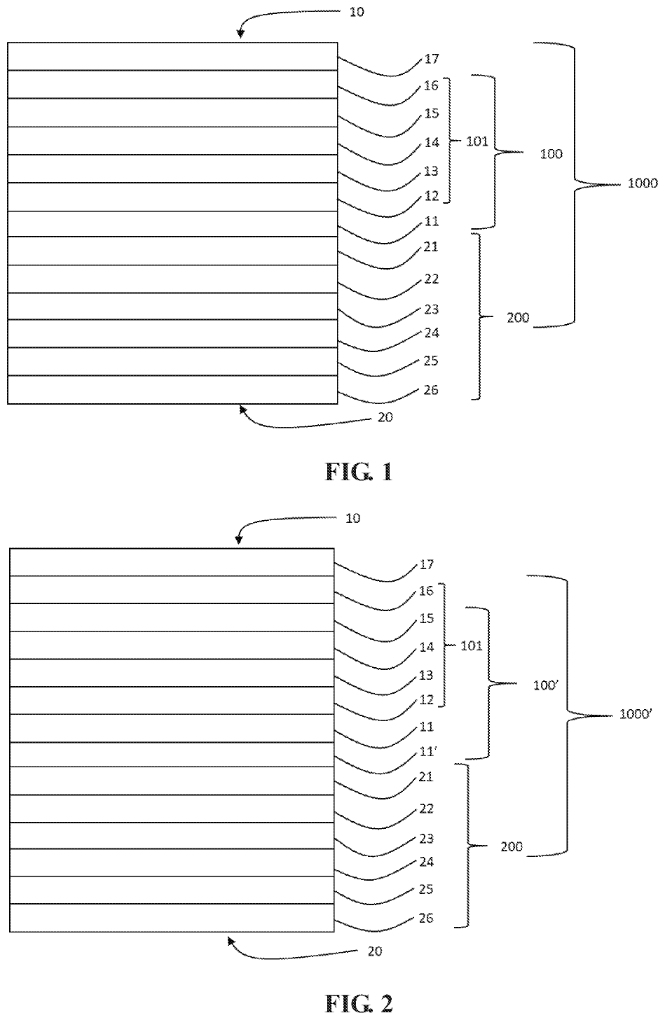

Referring to FIG. 2, in one embodiment of the disclosure, the organic light emitting module 100′ includes a thin film transistor substrate 11′ disposed on the lower substrate 21, a thin film transistor layer 11 disposed on the thin film transistor substrate 11′, an anode layer 12 disposed on the thin film transistor layer 11, a hole transporting layer 13 disposed on the anode layer 12, a light emitting layer 14 disposed on the hole transporting layer 13, an electron transporting layer 15 disposed on the light emitting layer 14, and a cathode layer 16 disposed on the electron transporting layer 15.

In detail, the anode layer 12, the hole transporting layer 13, the light emitting layer 14, the electron transporting layer 15, and the cathode layer 16 constitute an organic light emitting pixel 101 of the organic light emitting module 100′.

In detail, the cathode layer 16 includes transparent electrode material.

In detail, the transparent electrode material is indium tin oxide.

In detail, the lower substrate 21 is transparent substrate. The anode layer 12 of the organic light emitting module 100′ includes metallic electrode material to enhance reflection of light beams incident the polymer dispersed liquid crystal module 200.

In detail, because the metal electrode occupies a small area of the transparent display panel 1000′, the reflection effect of the metal electrode does not affect the effect of the transparent display.

In one embodiment of the disclosure, the transparent display panel 1000′ further includes a cover plate 17 disposed on the cathode layer 16.

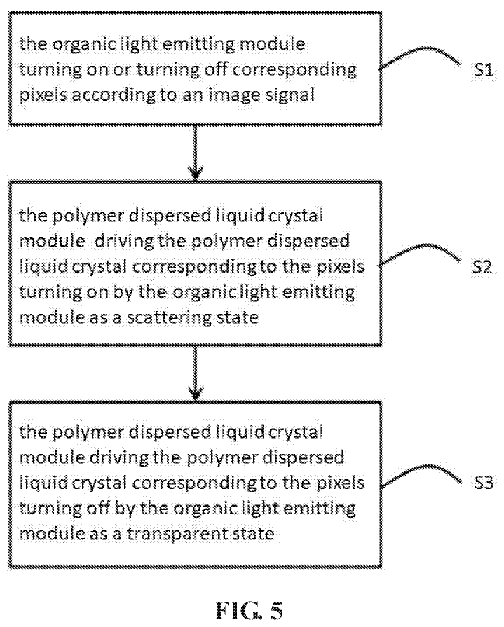

Referring to FIGS. 1, 3, and 5, furthermore, another embodiment of the disclosure provides a displaying method of a transparent display panel. The transparent display panel 1000″ includes an organic light emitting module 100″ and a polymer dispersed liquid crystal module 200″. The polymer dispersed liquid crystal module 200″ includes a lower substrate 21 and a display surface 20. The organic light emitting module 100″ is disposed on another side of the lower substrate 21. The organic light emitting module 100″ includes a display surface 10. The display surface 10 of the organic light emitting module 100″ faces an opposite direction of the display surface 20 of the polymer dispersed liquid crystal module 200″. The displaying method includes steps of:

Block S1: the organic light emitting module 100″ turning on or turning off corresponding pixels according to an image signal P1, P2, . . . ;

Block S2: the polymer dispersed liquid crystal module 200″ driving the polymer dispersed liquid crystal 23 corresponding to the pixels P1 turning on by the organic light emitting module 100″ as a scattering state; and

Block S3: the polymer dispersed liquid crystal module 200″ driving the polymer dispersed liquid crystal 23 corresponding to the pixels P2 turning off by the organic light emitting module 100″ as a transparent state.

In detail, each pixel P1, P2, . . . of the organic light emitting module 100″ includes, for example, three sub-pixels such as red sub-pixel R, green sub-pixel G, and blue sub-pixel B, but the disclosure is not limit thereto.

In detail, a resolution of the organic light emitting module 100″ is the same as a resolution of the polymer dispersed liquid crystal module 200″, and positions of pixel electrodes of the two modules are in one-to-one correspondence. However, the disclosure is not limited thereto. The resolution of the organic light emitting module 100″ may be proportional to the resolution of the polymer dispersed liquid crystal module 200″, and the positions of the pixel electrodes of two modules are generally corresponding to each other or having a corresponding relationship.

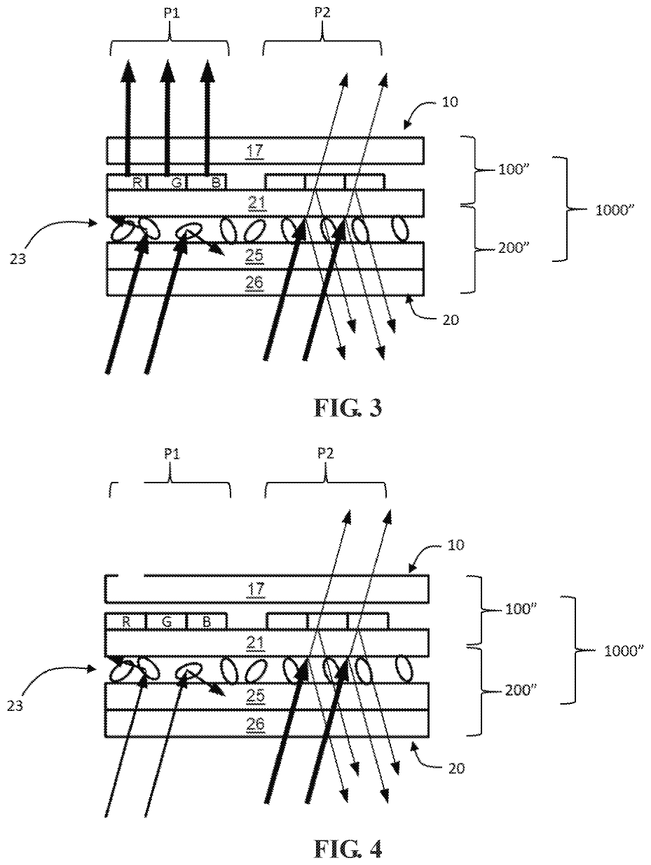

In detail, in order to clearly express light directions in application of the disclosure, some parts of the transparent display panel 1000″ in FIG. 3 are not shown. Only the lower substrate 21, the pixels P1, P2, the cover plate 17, the polymer dispersed liquid crystal material 23, the upper substrate 25 and the polarizer sheet 26 are shown in the figure.

Referring to FIG. 4, in one embodiment of the disclosure, the organic light emitting module 100″ is turned off and the polymer dispersed liquid crystal module 200″ is turned on to display when ambient light is greater than a predetermined luminance.

In detail, in order to clearly express light directions in application of the disclosure, some parts of the transparent display panel 1000″ in FIG. 4 are not shown. Only the lower substrate 21, the pixels P1, P2, the cover plate 17, the polymer dispersed liquid crystal material 23, the upper substrate 25 and the polarizer sheet 26 are shown in the figure.

Referring to FIG. 3, in one embodiment of the disclosure, the organic light emitting module 100″ and the polymer dispersed liquid crystal module 200″ are both turned on to undergo a transparent display when ambient light is lower than a predetermined luminance.

In detail, the transparent display panel 1000″ can adjust according to the intensity of the background light to improve contrast of display of the organic light emitting module 100″.

In comparison with prior art, the disclosure of the transparent display panel and the displaying method of the transparent display include the organic light emitting module disposed on another side of the lower substrate. The display surface of the organic light emitting module faces an opposite direction of the display surface of the polymer dispersed liquid crystal module. The polymer dispersed liquid crystal module driving the polymer dispersed liquid crystal corresponding to the pixels turning on by the organic light emitting module as a scattering state. The polymer dispersed liquid crystal module driving the polymer dispersed liquid crystal corresponding to the pixels turning off by the organic light emitting module as a transparent state. So that an embodiment of the transparent display panel of the disclosure behaves as a reflective display under strong ambient light to reduce power consumption and behave as a transparent display when ambient is darker and modulate ambient light by polymer dispersed liquid crystal to enhance contrast.

The present disclosure has been described by the above embodiments, but the embodiments are merely examples for implementing the present disclosure. It must be noted that the embodiments do not limit the scope of the invention. In contrast, modifications and equivalent arrangements are intended to be included within the scope of the invention.

What is claimed is:

1. A transparent display panel comprising:
an organic light emitting module; and
a polymer dispersed liquid crystal module, wherein the polymer dispersed liquid crystal module comprises:
a lower substrate; and
a display surface, wherein the organic light emitting module is disposed on another side of the lower substrate, the organic light emitting module comprises a display surface, wherein the display surface of the organic light emitting module faces an opposite direction of the display surface of the polymer dispersed liquid crystal module.

2. The transparent display panel according to claim 1, wherein the polymer dispersed liquid crystal module comprises:
a lower electrode layer disposed on a lower surface of the lower substrate;
a polymer dispersed liquid crystal material disposed under the lower electrode layer; and
an upper electrode layer disposed under the polymer dispersed liquid crystal material.

3. The transparent display panel according to claim 2, wherein the polymer dispersed liquid crystal module further comprises:
an upper substrate disposed under the upper electrode layer; and
a polarizer sheet disposed under the upper substrate, wherein a thickness of the polymer dispersed liquid crystal material is one fourth of a wavelength of incident light.

4. The transparent display panel according to claim 3, wherein the organic light emitting module and the polymer dispersed liquid crystal module share the lower substrate, and the organic light emitting module comprises:
a thin film transistor layer disposed on the lower substrate;
an anode layer disposed on the thin film transistor layer;
a hole transporting layer disposed on the anode layer;
a light emitting layer disposed on the hole transporting layer;
an electron transporting layer disposed on the light emitting layer; and
a cathode layer disposed on the electron transporting layer.

5. The transparent display panel according to claim 4, further comprising a cover plate disposed on the cathode layer.

6. The transparent display panel according to claim 3, wherein the organic light emitting module comprises:
a thin film transistor layer disposed on the lower substrate;
an anode layer disposed on the thin film transistor layer;
a hole transporting layer disposed on the anode layer;
a light emitting layer disposed on the hole transporting layer;
an electron transporting layer disposed on the light emitting layer; and
a cathode layer disposed on the electron transporting layer.

7. The transparent display panel according to claim 6, further comprising a cover plate disposed on the cathode layer.

8. A displaying method of a transparent display panel, wherein the transparent display panel comprises an organic light emitting module and a polymer dispersed liquid crystal module, the polymer dispersed liquid crystal module comprises a lower substrate and a display surface, the organic light emitting module is disposed on another side of the lower substrate, the organic light emitting module comprises a display surface, and the display surface of the organic light emitting module faces an opposite direction of the display surface of the polymer dispersed liquid crystal module, the displaying method comprises steps of:
the organic light emitting module turning on or turning off corresponding pixels according to an image signal;
the polymer dispersed liquid crystal module driving the polymer dispersed liquid crystal corresponding to the pixels turning on by the organic light emitting module as a scattering state; and
the polymer dispersed liquid crystal module driving the polymer dispersed liquid crystal corresponding to the pixels turning off by the organic light emitting module as a transparent state.

9. The displaying method of the transparent display panel according to claim 8, wherein the organic light emitting module is turned off and the polymer dispersed liquid crystal module is turned on to display when ambient light is greater than a predetermined luminance.

10. The displaying method of the transparent display panel according to claim 8, wherein the organic light emitting module and the polymer dispersed liquid crystal module are both turned on to undergo a transparent display when ambient light is lower than a predetermined luminance.

11. A transparent display panel comprising:
an organic light emitting module; and
a polymer dispersed liquid crystal module, wherein the polymer dispersed liquid crystal module comprises:
a lower substrate; and
a display surface, wherein the organic light emitting module is disposed on another side of the lower substrate, the organic light emitting module comprises a display surface, wherein the display surface of the organic light emitting module faces an opposite direction of the display surface of the polymer dispersed liquid crystal module and the organic light emitting module and the polymer dispersed liquid crystal module share the lower substrate.

12. The transparent display panel according to claim 11, wherein the organic light emitting module comprises:
a thin film transistor layer disposed on the lower substrate;
an anode layer disposed on the thin film transistor layer;
a hole transporting layer disposed on the anode layer;
a light emitting layer disposed on the hole transporting layer;
an electron transporting layer disposed on the light emitting layer; and
a cathode layer disposed on the electron transporting layer.

13. The transparent display panel according to claim 12, further comprising a cover plate disposed on the cathode layer.

14. The transparent display panel according to claim 12, wherein the polymer dispersed liquid crystal module comprises:
a lower electrode layer disposed on a lower surface of the lower substrate;
a polymer dispersed liquid crystal material disposed under the lower electrode layer; and
an upper electrode layer disposed under the polymer dispersed liquid crystal material.

15. The transparent display panel according to claim 14, wherein a thickness of the polymer dispersed liquid crystal material is one fourth of a wavelength of incident light.
